(19) United States
(12) Patent Application Publication
(10) Pub. No.: US 2016/0172577 A1
(43) Pub. Date: Jun. 16, 2016

(54) METHOD FOR FABRICATING PIEZOELECTRIC TRANSDUCER

(71) Applicant: NATIONAL TSING HUA UNIVERSITY, Hsinchu (TW)

(72) Inventors: Chien-Chong Hong, Hsinchu County (TW); Kuan-Wen Chen, Taichung City (TW)

(21) Appl. No.: 14/693,833

(22) Filed: Apr. 22, 2015

(30) Foreign Application Priority Data
Dec. 16, 2014 (TW) 103143784

(51) Int. Cl. H01L 41/257; H01L 41/31

(52) U.S. Cl. CPC H01L 41/257; H01L 41/31

(57) ABSTRACT

A method for fabricating a piezoelectric transducer is provided. The method includes providing a substrate on which a plurality of patterned electrodes are formed; providing a piezoelectric suspension, having a plurality of piezoelectric particles, on the substrate and the plurality of patterned electrodes; applying a voltage between the plurality of patterned electrodes to produce an electric field; and depositing the plurality of piezoelectric particles of the piezoelectric suspension on at least one of the plurality of patterned electrodes by the electric field to form a patterned piezoelectric membrane, and polarizing the piezoelectric membrane by the electric field.

### CROSS REFERENCE TO RELATED APPLICATIONS

The present application claims priority of Taiwan Patent Application No.103143784, filed on Dec. 16, 2014, the entirety of which is incorporated by reference herein.

### BACKGROUND OF THE DISCLOSURE

1. Field of the Disclosure

The present disclosure relates to a method for fabricating a piezoelectric transducer, and in particular to a method for fabricating a piezoelectric transducer which can simplify the process and reduce the processing time.

2. Description of the Related Art

A piezoelectric transducer is a device that achieves conversion from mechanical to electrical energy or vice versa by using the piezoelectric effect of piezoelectric materials, such that it can be simultaneously used as a sensor and an actuator and therefore having a huge potential for development.

In the field of Microelectromechanical Systems (MEMS), various types of components, such as sensors and actuators, are fabricated and integrated into a small chip (also called a “microchip”). Thus, it is very important to pattern/micropattern those components. Presently, photolithography and soft lithography are the methods that are usually used, and ink jet printing and injection molding are used relatively less frequently, for patterning a piezoelectric membrane of a piezoelectric transducer. However, there are lots of disadvantages, such as poor integration (needing to be treated by heat or chemicals, etc.), complicated processes, time consuming, or high costs, in the above methods. Therefore, a novel method for patterning the piezoelectric membrane which can overcome those disadvantages is needed.

In the traditional piezoelectric membrane formation processes, to improve piezoelectric properties of the piezoelectric membrane, an extra electric field, tensile stress, annealing, and so forth may be further applied to the piezoelectric (material) membrane so as to make the electric dipole moment of molecules thereof arrange regularly, i.e. a polarization process. Consequently, the complexity of the process and the processing time for forming the piezoelectric membrane are significantly increased.

### BRIEF SUMMARY OF THE DISCLOSURE

In view of the aforementioned known problems, an object of the disclosure is to provide a method for fabricating a piezoelectric transducer capable of integrating the patterning and the polarization processes of the piezoelectric membrane into a single process, so as to simplify the process and reduce the processing time.

An embodiment of the disclosure provides a method for fabricating a piezoelectric transducer. The method includes providing a substrate on which a plurality of patterned electrodes are formed; providing a piezoelectric suspension, having a plurality of piezoelectric particles, on the substrate and the plurality of patterned electrodes; applying a voltage between the plurality of patterned electrodes to produce an electric field; and depositing the plurality of piezoelectric particles of the piezoelectric suspension on at least one of the plurality of patterned electrodes by the electric field to form a patterned piezoelectric membrane, and polarizing the piezoelectric membrane by the electric field.

In another embodiment, the method further includes removing the residue of the piezoelectric suspension and removing the voltage to accomplish fabrication of the piezoelectric transducer.

In another embodiment, polarizing the piezoelectric membrane is performed within the piezoelectric suspension.

In another embodiment, patterning and polarizing the piezoelectric membrane are performed at the same time.

In another embodiment, the operation time for patterning and polarizing the piezoelectric membrane is about 1 to 40 minutes.

In another embodiment, patterning and polarizing the piezoelectric membrane are performed at a temperature of about 0 to 90 degrees on the Celsius scale.

In another embodiment, the voltage is a direct current (DC) voltage about 1 to 4 volts.

In another embodiment, the plurality of patterned electrodes include a pair of concentric ring electrodes, and the plurality of piezoelectric particles of the piezoelectric suspension are deposited on one of the ring electrodes.

In another embodiment, the plurality of patterned electrodes include three concentric ring electrodes, and the plurality of piezoelectric particles of the piezoelectric suspension are deposited on two of the ring electrodes.

In another embodiment, the solvent of the piezoelectric suspension is an organic solvent having a boiling point that is greater than 150 degrees on the Celsius scale.

In another embodiment, the plurality of piezoelectric particles comprise bismuth ferrite or piezoelectric polymer, such as polyvinylidene difluoride (PVDF) or polyvinyledene difluoride-co-trifluoroethylene (P(VDF-TrFE)).

### BRIEF DESCRIPTION OF THE DRAWINGS

The disclosure can be more fully understood by reading the subsequent detailed description and examples with references made to the accompanying drawings, wherein:

FIGS. 1A-1C are schematic views of a method for fabricating a piezoelectric transducer, in accordance with an embodiment of the disclosure;

FIG. 2 is a schematic view of a piezoelectric transducer, in accordance with an embodiment of the disclosure;

FIG. 3 is a schematic view of a piezoelectric transducer, in accordance with another embodiment of the disclosure; and

FIG. 4 is a flow chart of a method for fabricating a piezoelectric transducer, in accordance with an embodiment the disclosure.

### DETAILED DESCRIPTION OF THE DISCLOSURE

In order to illustrate the purposes, features and advantages of the disclosure, the embodiments and figures of the disclosure are shown in detail as follows.

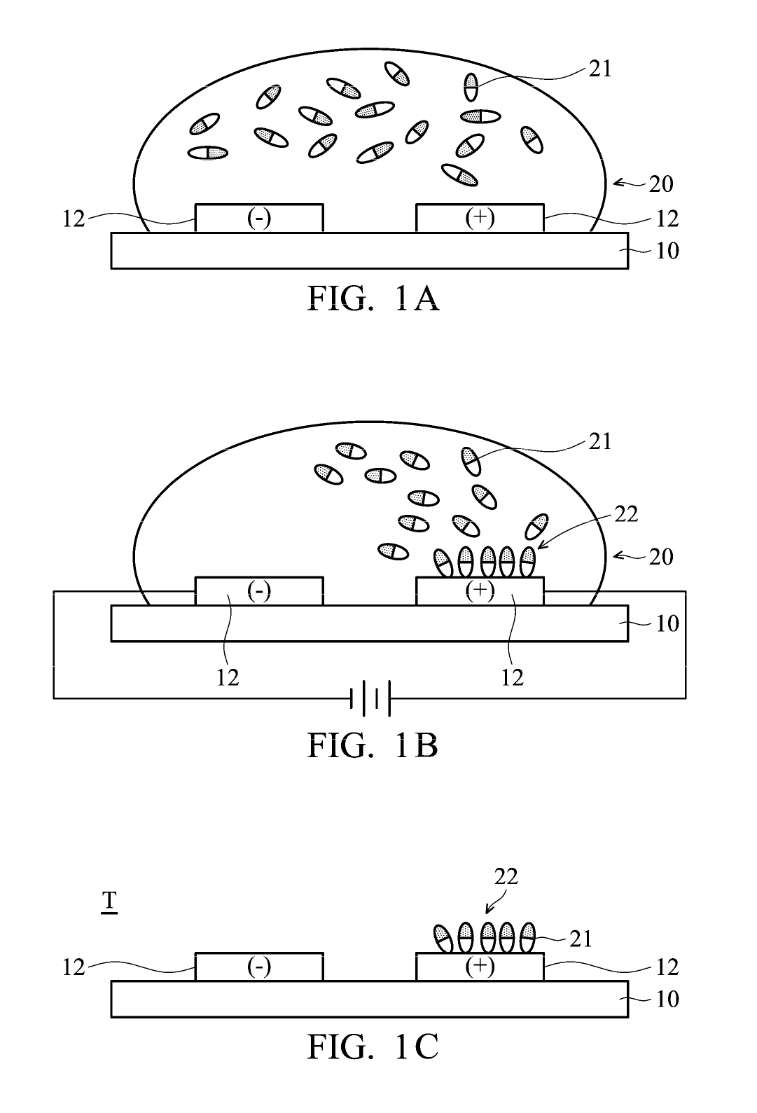

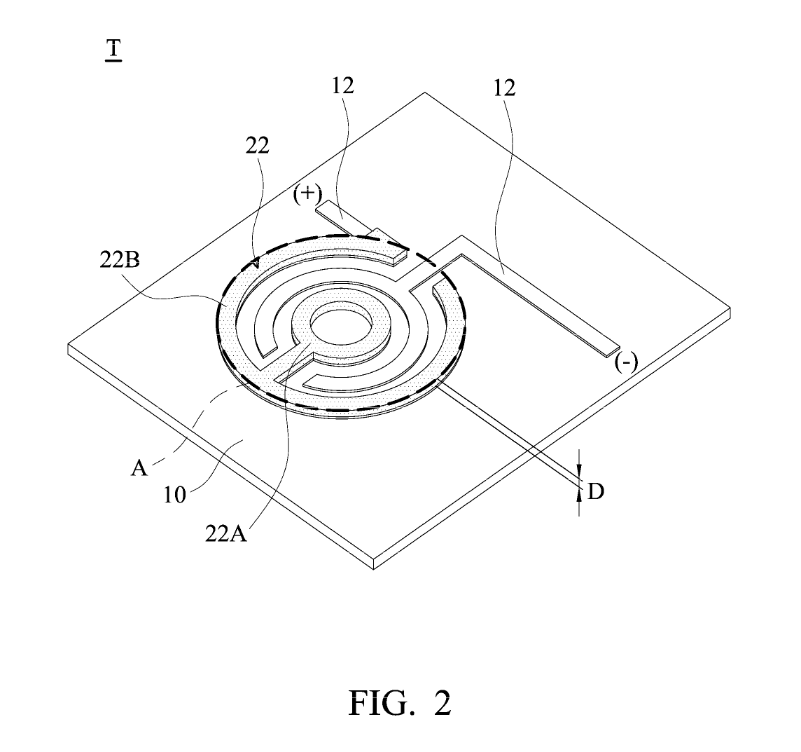

FIGS. 1A-1C are schematic views of a method for fabricating a piezoelectric transducer, in accordance with an embodiment of the disclosure. Referring to FIG. 1A firstly, a substrate 10, such as a glass substrate or a plastic (e.g. cyclic olefin copolymer (COC) material) substrate is provided. The substrate 10 has a plurality of patterned electrodes 12 formed thereon (the plurality of patterned electrodes 12 may be a pair of concentric ring electrodes spaced apart from each other, see FIG. 2). The plurality of patterned electrodes 12 may comprise Au, Cr, Pt, Ti, Al, a combination thereof, or other metal materials with good conductivity, and be formed by depositing and patterning processes, wherein the depositing and patterning processes are known skills in the field of MEMS and thus are not described here.

Referring to FIG. 1A, a piezoelectric suspension 20 is provided on the substrate 10 and the plurality of patterned electrodes 12. In this embodiment, the piezoelectric suspension 20 is composed of a plurality of piezoelectric particles 21 dissolved in an organic solvent having a boiling point that is greater than 150 degrees on the Celsius scale (e.g. dimethyl sulfoxide (DMSO) with the boiling point of about 189 degrees on the Celsius scale). The plurality of piezoelectric particles 21 may comprise bismuth ferrite or piezoelectric polymer, such as polyvinylidene difluoride (PVDF) or polyvinyledene difluoride-co-trifluoroethylene (P(VDF-TrFE)).

Referring to FIG. 1B, after providing the piezoelectric suspension 20 on the substrate 10 and covering the plurality of the patterned electrodes 12, a direct current (DC) voltage is applied between the plurality of the patterned electrodes 12 to form an electric field (not shown). Under the influence of the electric field, the plurality of piezoelectric particles 21 within the piezoelectric suspension 20 will move towards a positive pole of the plurality of patterned electrodes 12 and are deposited on the positive pole to further form a patterned piezoelectric membrane 22. The above mechanism is based on electrophoretic deposition (EPD). It should be realized that the plurality of piezoelectric particles 21 used in this embodiment will carry negative charges on their surfaces under the influence of the electric field and therefore can be deposited on the positive pole of the plurality of patterned electrodes 12. However, in some embodiments of the disclosure, the plurality of piezoelectric particles 21 which will carry positive charges on their surfaces under the influence of the electric field may also be used, and those piezoelectric particles 21 are deposited on the negative pole of the plurality of patterned electrodes 12.

Note that the boiling point of the solvent of the piezoelectric suspension 20 is a key factor affecting the EPD. While an organic solvent having a boiling point that is greater than 150 degrees on the Celsius scale is chosen for the solvent of the piezoelectric suspension 20, it is non-volatile at room temperature and therefore the patterned piezoelectric membrane 22 can be formed successfully. Conversely, while an organic solvent having a lower boiling point (e.g. methyl ethyl ketone (MEK) with a boiling point of about 80 degrees on the Celsius scale) is chosen for the solvent of the piezoelectric suspension 20, it is volatile at room temperature and therefore results in only a whole piece of piezoelectric membrane being formed (failure on the patterning process).

Furthermore, while the plurality of piezoelectric particles 21 are being deposited on the plurality of patterned electrodes 12, the electric dipole moment of molecules of the plurality of piezoelectric particles 21 will also be regularly arranged under the influence of the same electric field (as shown in FIG. 1B). That is, electrical polarization occurs simultaneously in the patterned piezoelectric membrane 22. In this embodiment, piezoresponse force microscopy (PFM) or an X-ray diffraction method may be used to measure whether the patterned piezoelectric membrane is polarized or not.

In this embodiment, the primary operating parameters for the piezoelectric membrane formation process (including the above patterning and polarizing processes) include operating temperature (about 0 to 90 degrees on the Celsius scale), applied DC voltage (about 1 to 4 volts), and operating/deposition time (about 1 to 40 minutes). For example, when the operating parameters for the piezoelectric membrane formation process are a temperature of about 25 degrees on the Celsius scale, an applied voltage of about 2.5 volts, and a deposition time of about 10 minutes, a piezoelectric membrane having a depth of about 3 μm and a piezoelectric coefficient arriving at 5.99 pm/V can be formed.

Referring to FIG. 1C, after the patterned and polarized piezoelectric membrane 22 is formed on the positive pole of the plurality of patterned electrodes 12, the residue of the piezoelectric suspension 20 is removed and then the DC voltage is further removed, such that fabrication of a piezoelectric transducer T is accomplished.

In the above method for fabricating the piezoelectric transducer T, the patterning and the polarization processes of the piezoelectric membrane can be integrated into a single process (the patterning and the polarization processes are performed at the same time and under the same electric field), thus effectively simplifying the process and reducing the processing time. However, in the traditional piezoelectric membrane formation processes, the patterning and the polarization processes are two separate and independent processes, such that the entire process may take from one to several hours. It should be noted that, in some embodiments of the disclosure, an extra polarization process using parallel electric fields, tensile stress, annealing, and so forth may also be added to the method for fabricating the piezoelectric transducer based on practical requirements.

The above method for fabricating the piezoelectric transducer T has several advantages: both the EPD and the electrical polarization directly use the electric field to interact with the plurality of piezoelectric particles without other chemical etching, heat, or high energy processes, such that the fabrication compatibility is increased and the production cost is reduced. Moreover, the electrical polarization is performed within the piezoelectric suspension, and therefore, compared to the traditional method which uses an extra electric field to polarize the (solid) piezoelectric membrane, it can rotate the plurality of piezoelectric particles more easily and rapidly. Thus, the applied electric field can be decreased and the (polarization) processing time can also be reduced.

Referring to FIG. 2, a piezoelectric transducer T according to an embodiment of the disclosure primarily includes a substrate 10, a pair of patterned electrodes 12 (a positive pole and a negative pole) formed on the substrate 10, and a piezoelectric membrane 22 formed on the positive pole of the pair of patterned electrodes 12. As shown in FIG. 2, the positive pole of the pair of patterned electrodes 12 includes an inner ring portion (small ring) and an outer ring portion (big ring) connected to each other, and the negative pole of the pair of patterned electrodes 12 also includes a ring portion situated between the inner ring portion and the outer ring portion of the positive pole. Moreover, the positive and negative poles are spaced apart from each other and arranged in concentric circles. Using the fabrication method as shown in FIGS. 1A-1C, a patterned piezoelectric membrane 22 with an inner ring portion 22A and an outer ring portion 22B can be deposited and formed on the positive pole of the pair of patterned electrodes 12, and the piezoelectric membrane 22 has also been polarized. In this embodiment, the depth D of the piezoelectric membrane 22 is about 3 μm and the area A thereof is only about 0.13 mm².

With the special structure of the piezoelectric membrane 22, the piezoelectric transducer T can be used as a receiver or transmitter for ultrasonic waves (with an operating frequency that is greater than about 20 kHz). For example, when an ultrasonic wave propagates to the piezoelectric transducer T, it may cause the piezoelectric membrane 22 to vibrate in resonance, and then the piezoelectric membrane 22 can transform this mechanical energy into an electrical signal. Accordingly, the intensity of the ultrasonic wave signal can be determined by measuring the intensity of the electrical signal (wherein the piezoelectric transducer T is used as a receiver). Conversely, when an electrical signal is applied to the piezoelectric transducer T, the piezoelectric membrane 22 can transform this electrical signal into mechanical energy, such as a high-frequency vibration, and then the high-frequency vibration will drive the ambient air to vibrate correspondingly, thus producing an ultrasonic wave signal (wherein the piezoelectric transducer T is used as a transmitter). Moreover, the piezoelectric transducer T has a small feature size, and therefore can be easily integrated into a MEMS microchip.

In some embodiments of the disclosure, two piezoelectric transducers T secured by at least a double-faced adhesive tape having a depth on the scale of tens of micrometers, with their piezoelectric membrane 22 facing to each other, may further be made. Accordingly, one of the piezoelectric transducers T can be used as a transmitter and the other can be used as a receiver, thus accomplishing an ultrasonic wave transceiver.

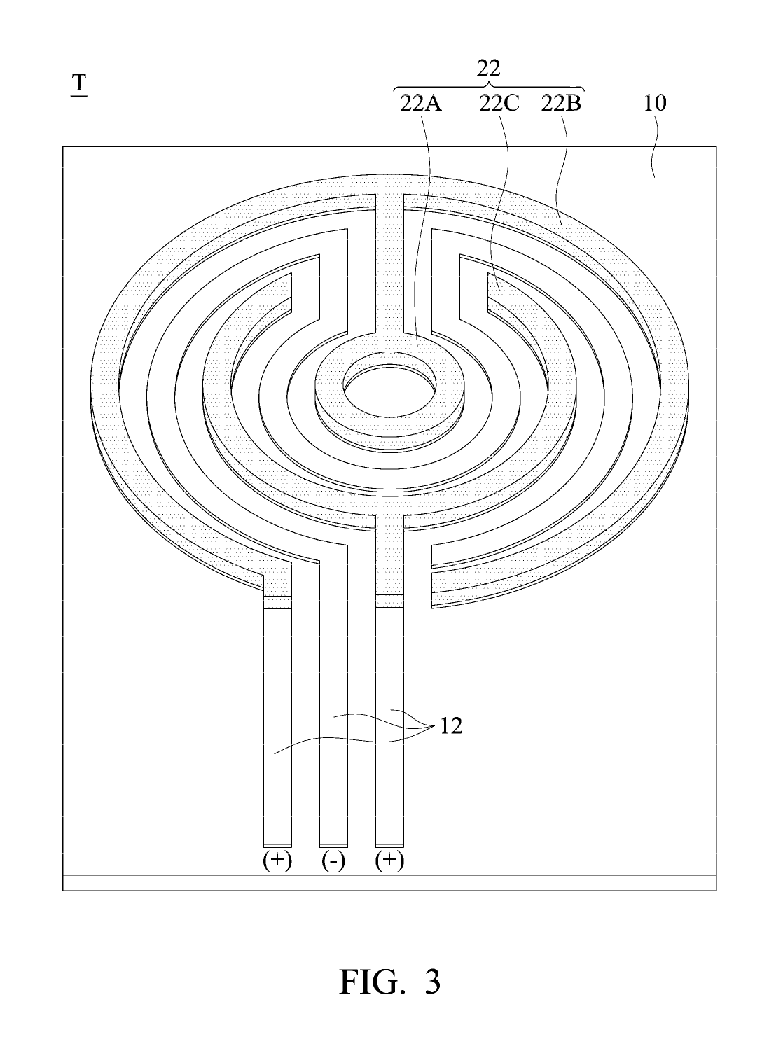

Referring to FIG. 3, a piezoelectric transducer T according to another embodiment of the disclosure primarily includes a substrate 10, three patterned electrodes 12 (two positive poles and a negative pole) formed on the substrate 10, and a piezoelectric membrane 22 formed on the positive poles of the patterned electrodes 12. As shown in FIG. 3, the outer positive pole of the patterned electrodes 12 includes an inner ring portion (small ring) and an outer ring portion (big ring) connected to each other, the inner positive pole of the patterned electrodes 12 also includes a ring portion situated between the inner ring portion and the outer ring portion of the outer positive pole, and the negative pole of the patterned electrodes 12 includes a connected double ring portion situated between the outer and inner positive poles. Moreover, the positive and negative poles are spaced apart from each other and arranged in concentric circles. Using the fabrication method as shown in FIGS. 1A-1C, a patterned piezoelectric membrane 22 with an inner ring portion 22A, an outer ring portion 22B, and an intermediate ring portion 22C can be deposited and formed on two positive poles of the patterned electrodes 12, and the piezoelectric membrane 22 has also been polarized. It should be noted that the piezoelectric membrane 22 of the piezoelectric transducer T in this embodiment has an additional intermediate ring portion 22C compared with the piezoelectric membrane 22 of the piezoelectric transducer T in FIG. 2, therefore having better piezoelectric conversion efficiency.

Though the piezoelectric membranes in the above embodiments are all ring shaped, the disclosure is not restricted. The plurality of patterned electrodes can be designed to have different shapes according to different applications (e.g. micropumps, pressure sensors, or biosensors) to fabricate various types of piezoelectric membranes with different patterns.

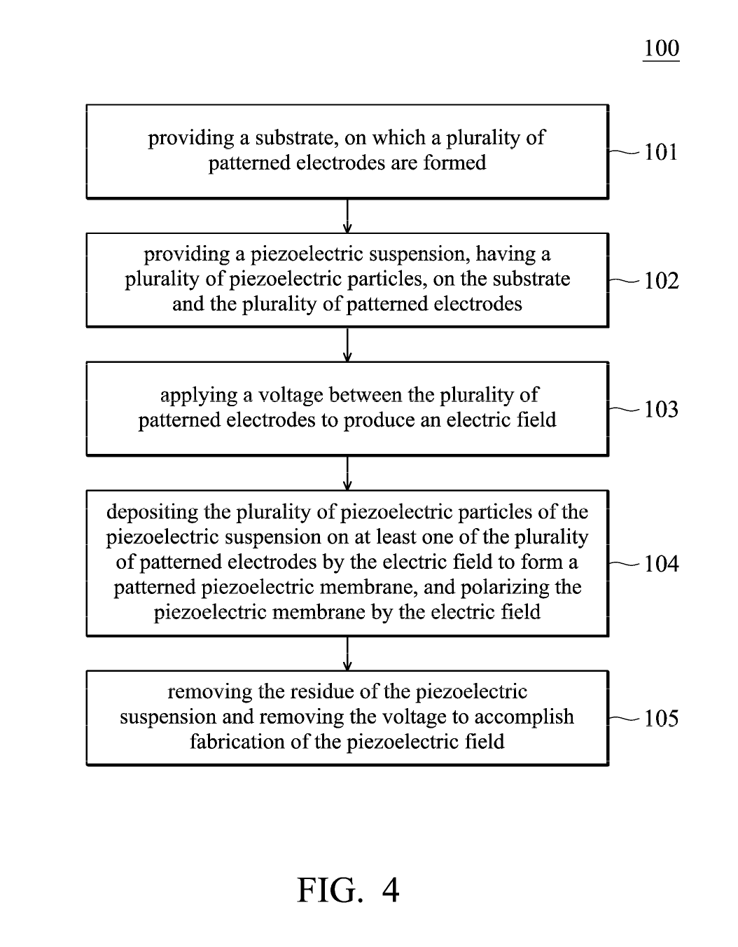

As described above, the disclosure provides a method for fabricating a miniaturized piezoelectric transducer, in which the steps include (referring to the flow chart 100 of the fabrication method in FIG. 4): providing a substrate, on which a plurality of patterned electrodes are formed (step 101); providing a piezoelectric suspension, having a plurality of piezoelectric particles, on the substrate and the plurality of patterned electrodes (step 102); applying a voltage between the plurality of patterned electrodes to produce an electric field (step 103); depositing the plurality of piezoelectric particles of the piezoelectric suspension on at least one of the plurality of patterned electrodes by the electric field to form a patterned piezoelectric membrane, and polarizing the piezoelectric membrane by the electric field (step 104); and removing the residue of the piezoelectric suspension and removing the voltage to accomplish fabrication of the piezoelectric transducer (step 105). The feature of the above fabrication method is that the patterning and the polarization processes of the piezoelectric membrane can be integrated into a single process (the patterning and the polarization processes are performed at the same time and under the same electric field), thus effectively simplifying the process and reducing the processing time.

While the disclosure has been described by way of example and in terms of the preferred embodiments, it is to be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating a piezoelectric transducer, comprising:
providing a substrate, on which a plurality of patterned electrodes are formed;
providing a piezoelectric suspension, having a plurality of piezoelectric particles, on the substrate and the plurality of patterned electrodes;
applying a voltage between the plurality of patterned electrodes to produce an electric field; and
depositing the plurality of piezoelectric particles of the piezoelectric suspension on at least one of the plurality of patterned electrodes by the electric field to form a patterned piezoelectric membrane, and polarizing the piezoelectric membrane by the electric field.

2. The method as claimed in claim 1, further comprising:
removing a residue of the piezoelectric suspension and removing the voltage to accomplish fabrication of the piezoelectric transducer.

3. The method as claimed in claim 1, wherein polarizing the piezoelectric membrane is performed within the piezoelectric suspension.

4. The method as claimed in claim 1, wherein patterning and polarizing the piezoelectric membrane are performed at the same time.

5. The method as claimed in claim 4, wherein an operation time for patterning and polarizing the piezoelectric membrane is about 1 to 40 minutes.

6. The method as claimed in claim 1, wherein patterning and polarizing the piezoelectric membrane are performed at a temperature of about 0 to 90 degrees on the Celsius scale.

7. The method as claimed in claim 1, wherein the voltage is a direct current (DC) voltage about 1 to 4 volts.

8. The method as claimed in claim 1, wherein the plurality of patterned electrodes include a pair of concentric ring electrodes, and the plurality of piezoelectric particles of the piezoelectric suspension are deposited on one of the ring electrodes.

9. The method as claimed in claim 1, wherein the plurality of patterned electrodes include three concentric ring electrodes, and the plurality of piezoelectric particles of the piezoelectric suspension are deposited on two of the ring electrodes.

10. The method as claimed in claim 1, wherein a solvent of the piezoelectric suspension is an organic solvent having a boiling point that is greater than 150 degrees on the Celsius scale.

11. The method as claimed in claim 1, wherein the plurality of piezoelectric particles comprise bismuth ferrite or piezoelectric polymer, such as polyvinylidene difluoride (PVDF) or polyvinyledene difluoride-co-trifluoroethylene (P(VDF-TrFE)).
